(19) United States
(12) Patent Application Publication
(10) Pub. No.: US 2026/0189857 A1
(43) Pub. Date: Jul. 2, 2026

(54) MEMS ELEMENT FOR MOVING A MASS ELEMENT OF AN ACOUSTIC TRANSDUCER FOR GENERATING AND/OR RECEIVING ACOUSTIC SIGNALS, AND ACOUSTIC TRANSDUCER HAVING SUCH A MEMS ELEMENT

(71) Applicant: Robert Bosch GmbH, Stuttgart (DE)

(72) Inventor: Reinhold Roedel, Reutlingen (DE)

(21) Appl. No.: 18/868,478

(22) PCT Filed: May 15, 2023
(86) PCT No.: PCT/EP2023/062993

§ 371 Date: Feb. 11, 2025

(30) Foreign Application Priority Data
Jun. 1, 2022 (DE) 10 2022 205 608.6

(51) Int. Cl. H04R 17/02; B81B 3/00; B81C 1/00

(52) U.S. Cl. CPC H04R 17/02; B81B 3/007; B81C 1/00658; B81B 2201/0257; B81B 2203/0118; B81B 2203/0315; B81C 2201/0115; H04R 2201/003; H04R 2400/01

(57) ABSTRACT

A MEMS element for moving a mass element of an acoustic transducer for generating and/or receiving acoustic signals. The MEMS element is produced from a substrate. The MEMS element has an actuator element with at least one piezo element, applied to the actuator element, for moving the actuator element in a vertical direction in relation to the main extension plane of the MEMS element. The geometry of the actuator element is defined by a cavity in the substrate. The MEMS element has a connecting element, arranged on the actuator element, for connecting the actuator element to the mass element of the acoustic transducer and for transferring the movement of the actuator element to the mass element. The connecting element has a greater stiffness than the actuator element. The cavity is formed in the substrate so that the substrate forms a depth stop for the actuator element.

### FIELD

The present invention relates to a MEMS element for moving a mass element of an acoustic transducer for generating and/or receiving acoustic signals.

The idea is to set a mass element of the acoustic transducer in stroke motion by means of one or more MEMS elements and thus to emit the sound or to be deflected in the opposite direction by a sound and to detect the acoustic signal via the MEMS element.

### BACKGROUND INFORMATION

The problem with conventional MEMS elements is that, due to the design of the MEMS element and of the associated production process, the depth stop often has a corresponding deviation from a target specification and the accuracy for adjusting the depth stop is consequently insufficient. This poses the risk that the breaking limit for the actuator element will be exceeded and the MEMS element could thus be destroyed.

Furthermore, in conventional MEMS elements, the design of the actuator element, which directly affects the resonance frequency, is created by a trench process, the dimensions of which may be inaccurate due to tilting and widening due to the process. Consequently, MEMS elements according to the related art can have large deviations from one another with respect to their resonance frequencies.

The present invention present is intended to address the stated problems.

### SUMMARY

The present invention relates to a MEMS element for moving a mass element of an acoustic transducer for generating and/or receiving acoustic signals.

One aspect of the present invention is that the MEMS element is produced from a substrate, wherein the MEMS element has an actuator element with at least one piezo element, applied to the actuator element, for moving the actuator element in a vertical direction in relation to the main extension plane of the MEMS element, and wherein the geometry of the actuator element is defined by a cavity in the substrate, and wherein the MEMS element has a connecting element, arranged on the actuator element, for connecting the actuator element to the mass element of the acoustic transducer and for transferring the movement of the actuator element to the mass element, wherein the connecting element has a greater stiffness than the actuator element, and wherein the cavity is formed in the substrate in such a way that the substrate itself forms a depth stop for the actuator element in the vertical direction.

An advantage here is that both the geometry of the actuator element and the design of the depth stop can be implemented more precisely by means of the cavity than in the related art. This in turn means that the resonance frequency of the actuator element can be adjusted more precisely and that the risk of exceeding the breaking limit of the actuator element can be reduced.

A further advantage is that, by adjusting the stiffnesses, it is possible to move the actuator element easily and yet, due to the increased stiffness of the connecting element, to make it possible to transfer the movement to the mass element of the acoustic transducer with as little loss as possible.

An acoustic transducer is a system that converts a non-mechanical form of energy, typically electrical energy, into mechanical energy via a piezo element in a suitable manner in order to generate an acoustic signal thereby. The conversion effect can typically be reversed in the same way, which means that the mechanical energy of received acoustic signals is converted into electrical energy, wherein the generated electrical signal can be evaluated accordingly. In particular, the acoustic transducer may, for example, be designed as an ultrasonic transducer and receive or emit corresponding ultrasonic signals.

Accordingly, the acoustic may, for example, be used in a microphone or a loudspeaker or in an ultrasonic sensor system.

The emitted acoustic signal is generated by a mass element of the acoustic transducer that is set in motion by the MEMS element, or the mass element is set in motion by the received acoustic signal, which can be detected by the MEMS element. The mass element may, for example, be designed as a membrane or in the manner of a piston.

In particular, a plurality of acoustic transducers can form an acoustic sensor array.

A MEMS element is a microelectronic-mechanical system, which in particular combines or integrates electronic and mechanical components in the smallest possible space.

The MEMS element has an actuator element, which may, for example, be designed as a cantilever or in the manner of a membrane and can be set in motion by the piezo element or can pass movement to the piezo element for evaluation.

Here, the actuator element is arranged on a suspension element, which is designed to be stiffer in comparison to the actuator element and, for example, represents the rest of the substrate of the MEMS element. Furthermore, a connecting element, which serves to connect the actuator element to the mass element and accordingly to make movement possible in either one or the other direction, is arranged on the actuator element.

The connecting element may comprise individual or all layers that are also present in the actuator element, and may accordingly be designed as a continuation of the actuator element or may also protrude beyond the actuator element at least in a vertical direction to the main extension plane of the actuator element.

The piezo element may, for example, be designed as a piezoelectric layer.

According to an example embodiment of the present invention, the substrate used may, for example, be a suitably preprocessed silicon wafer, which can then be processed accordingly in order to obtain the desired design of the MEMS element, having the suspension element, the actuator element, and the connecting element. The substrate used may also be a combination of wafers, which are, for example, connected via a wafer bond and can each comprise layer systems and structuring. For example, a cavity SOI wafer would also be conceivable as a substrate.

Stiffness is a quantity in engineering mechanics that describes the relationship between the load acting on a body and its elastic deformation. The stiffness of a body in particular depends on its material and geometry.

A cavity is a hollow space in the substrate.

The cavity in the substrate is in particular parallel to the main extension plane and below the actuator element.

Furthermore, the depth stop is a stop for the actuator element, which stops a movement of the actuator element at a certain point. In particular, the actuator element is designed as a region of the upper side of the cavity, wherein the depth stop represents a region of the lower side of the cavity.

One example embodiment of the present invention provides that the depth stop is defined by a height of the cavity.

An advantage here is that the height of the cavity in the substrate can be adjusted very precisely in terms of process technology.

The height of the cavity is the distance between the floor and the ceiling of the cavity in a state in which the MEMS element is not loaded, i.e., when the ceiling and the floor of the cavity are substantially parallel to one another.

One example embodiment of the present invention provides that the stiffness of the actuator element and/or of the connecting element is adjusted depending on the material and/or thickness and/or structuring of the corresponding element.

An advantage here is that this provides an easy way to adjust the stiffnesses of the corresponding elements as desired.

Material refers to the chemical composition of the corresponding element, which can affect its stiffness accordingly.

The term “structuring” refers to the shape of an element, which may, for example, have corresponding recesses or passages in order to change its stiffness. For example, the actuator element may be designed in the shape of a spoke in order to keep the stiffness low, whereas the suspension element and the connecting element do not have corresponding recesses in order to keep the stiffness high in comparison.

Thickness is the extension of the element in a vertical direction in relation to the main extension plane of the MEMS element. Theoretically, this could also fall under the term “structuring” but is explicitly highlighted here again due to the particular importance of the thickness on the stiffness properties of the element.

A further example embodiment of the present invention provides that the connecting element is arranged laterally on the actuator element and forms a stump, wherein the cavity is open in such a way that the connecting element is separated from the rest of the substrate.

An advantage here is that the geometry of the actuator element, and thus the resonance frequency, is defined by the lateral dimensions of the cavity, which can usually be adjusted very precisely depending on the chosen method for producing the cavity. The height of the depth stop d can in turn be defined by the height of the cavity, which can likewise usually be adjusted very precisely depending on the chosen method for producing the cavity. Furthermore, the MEMS element can be produced particularly easily from a substrate with a cavity, which keeps the costs for the MEMS element low.

In this case, the corresponding design of the actuator element may, for example, form a so-called cantilever, which can be understood as a movable arm.

The cavity is in particular open in one direction or on one side and particularly preferably open downward, as a result of which the connecting element is connected only to the actuator element and no longer to the rest of the substrate, which serves as a suspension element.

Here, the connecting element is, for example, arranged in the main extension plane at one end of the actuator element, for example on the right side, and the actuator element is in turn connected at its other end to the suspension element, i.e., on the left side.

The term “stump” can in particular be understood as a so-called stub.

According to one example embodiment of the present invention, at least two piezo elements which can be controlled in a phase-shifted manner are applied to the actuator element.

An advantage here is that an S-shaped deflection can be provided, in which the stroke as well as the breaking strength of the actuator element can again be increased.

By means of the phase-shifted control, it can be achieved, for example, that one of the piezo elements is bent to the left while the other piezo element is bent to the right, as a result of which a corresponding deformation of the actuator element can occur due to the position of the piezo element on the actuator element.

According to a further example embodiment of the present invention, the cavity has regions each of a different height, wherein the region of the cavity with the lowest height in particular serves as a depth stop.

An advantage here is that the properties of the elements adjacent to the cavity can be influenced accordingly by the different heights. For example, this can influence the stiffness of the actuator element.

According to a further example embodiment of the present invention, the actuator element and the connecting element are arranged concentrically in the main extension plane of the MEMS element, wherein the connecting element is arranged centrally, and wherein the cavity is parallel to the main extension plane and below the actuator element and connecting element.

An advantage here is that a different design of the actuator element and of the connecting element makes it possible in particular to more uniformly transfer the movement of the actuator element to the mass element of the acoustic transducer, since the connecting element is moved accordingly from a plurality of sides by means of the actuator element.

The actuator element may, for example, be designed in the manner of a membrane and be arranged accordingly around the connecting element, for example in the form of a circle from a perspective from above onto the MEMS element, although another geometry would also be conceivable.

According to a further example embodiment of the present invention, the cavity has a lower height in the region of the connecting element than in the region of the actuator element so that an indirect depth stop for the actuator element is formed via the connecting element.

An advantage here is that the depth stop can be adjusted better due to the lower height of the cavity in the region of the connecting element, whereas an improved damping property of the actuator element can be achieved in the region of the actuator element due to the comparatively greater height.

The present invention also relates to an acoustic transducer with a MEMS element according to the present invention, wherein the actuator element of the MEMS element is connected to a mass element of the acoustic transducer via the connecting element of the MEMS element.

### BRIEF DESCRIPTION OF THE DRAWINGS

FIG. 1 shows a lateral cross-section of an acoustic transducer with a first embodiment of a MEMS element designed according to the present invention.

FIG. 2 shows a lateral cross-section of an acoustic transducer with a second embodiment of a MEMS element designed according to the present invention.

FIG. 3A-3D shows method steps for producing a MEMS element according to the related art.

FIG. 4A-4C shows method steps for producing a MEMS element according to the first embodiment of FIG. 1.

### DETAILED DESCRIPTION OF EXAMPLE EMBODIMENTS

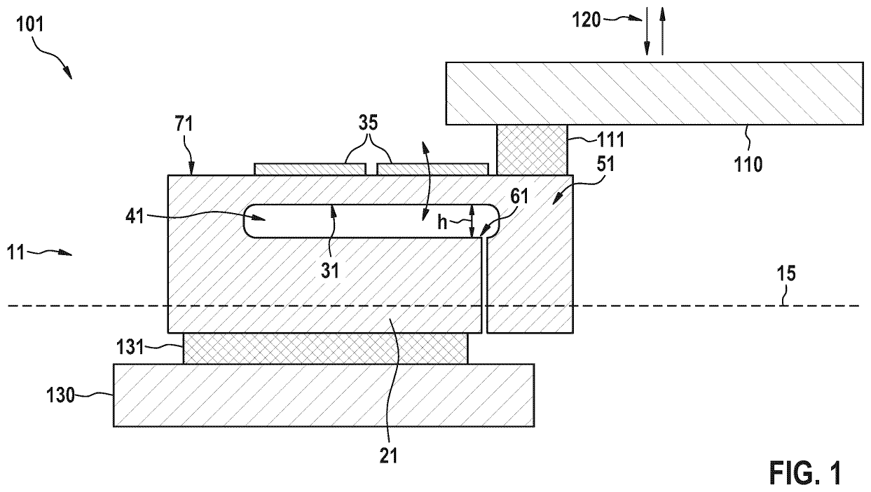

FIG. 1 shows a lateral cross-section of an acoustic transducer with a first embodiment of a MEMS element designed according to the present invention.

Shown is an acoustic transducer 101 for generating and/or receiving acoustic signals 120. For this purpose, the acoustic transducer 101 has a mass element 110 and a MEMS element 11 for moving the mass element 110 of the acoustic transducer 101. Here, the MEMS element 11 is produced from a substrate 21.

The MEMS element 11 has an actuator element 31 with two piezo elements 35, applied to the actuator element 31, for moving the actuator element 31 in a vertical direction in relation to the main extension plane 15 of the MEMS element 11. In principle, a single piezo element 35 would also be conceivable here. Additionally, the MEMS element 11 can naturally also be used to detect a deflection of the mass element 110, due to a received acoustic signal 120, by the actuator element 31 and the piezo elements 35 applied thereto. The piezo elements 35 can be applied as corresponding piezo layers to the actuator element 31 and can be controlled or read out by electronics (not shown). In particular, the piezo elements 35 can be controlled in a phase-shifted manner in order to achieve an S-shaped deflection of the actuator element 31.

Furthermore, the MEMS element 11 has a connecting element 51, which is in particular directly connected to the actuator element 31, for connecting the actuator element 31 to the mass element 110 of the acoustic transducer 101 and for transferring the movement of the actuator element 31 to the mass element 110, wherein the connecting element 51 has a higher stiffness than the actuator element 31. The connecting element 51 can be connected to the mass element 110 via a connecting means 111, which is, for example, designed as an adhesive. The higher stiffness of the connecting element 51 in comparison to the stiffness of the actuator element 31 is achieved by the greater thickness of the connecting element 51 in comparison to the thickness of the actuator element 31, wherein thickness means the dimensions of the corresponding element 31, 51 in a vertical direction.

The actuator element 31 is also connected to a suspension element 71, which forms the rest of the substrate 21 and likewise has a higher stiffness than the actuator element 31, again achieved through a greater thickness.

Furthermore, the geometry of the actuator element 31 is defined by a cavity 41 in the substrate 21, wherein the cavity 41 is formed in the substrate 21 in such a way that the substrate 21 itself forms a depth stop 61 for the actuator element 31 in the vertical direction in relation to the main extension plane 15. Here, the depth stop 61 is defined by a height h of the cavity 41.

In particular, the connecting element 51 is arranged laterally on the actuator element 31 and forms a stump, wherein the cavity 41 is open in such a way that the connecting element 51 is separated from the rest of the substrate 21 and the actuator element 31 and the connecting element 51 are thus correspondingly movable. Due to the corresponding design, the actuator element 31 with the connecting element 51 can move around the suspension element 71 as a bearing point, which is represented by a corresponding double arrow. Alternatively, a depth stop could also be defined by a width of the opening between the connecting element 51 and the rest of the substrate 21.

The MEMS element 11 can also be connected to a carrier element 130, which is, for example, designed as a PCB, via a connection 131, which is again, for example, designed as an adhesive.

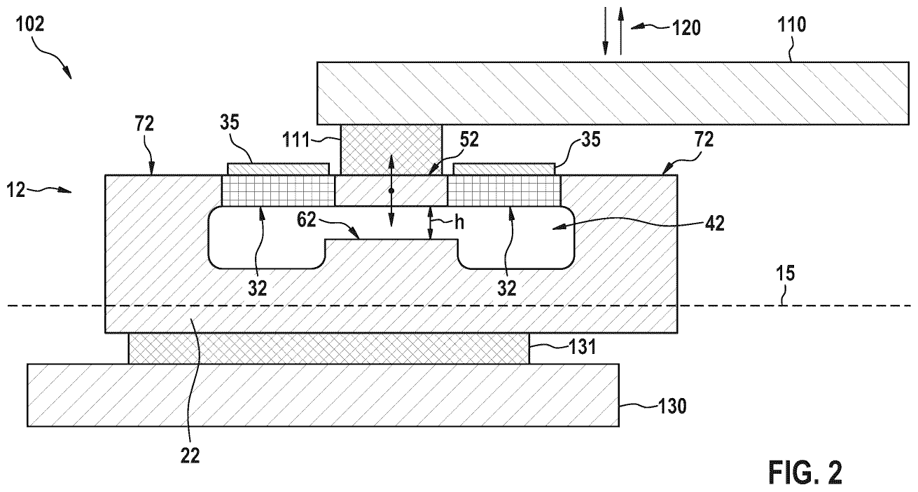

FIG. 2 shows a lateral cross-section of an acoustic transducer with a second embodiment of a MEMS element designed according to the present invention.

Shown is an acoustic transducer 102 which, like the acoustic transducer 101 of FIG. 1, serves to generate and/or receive acoustic signals 120. For this purpose, the acoustic transducer 102 again has a mass element 110 and a MEMS element 12 for moving the mass element 110 of an acoustic transducer 102. Here, the MEMS element 12 is produced from a substrate 22.

In addition, the MEMS element 12 has an actuator element 32 with two piezo elements 35, applied to the actuator element 32, for moving the actuator element 32 in a vertical direction, represented by the double arrow, in relation to the main extension plane 15 of the MEMS element 12. Alternatively, it would also be conceivable to use a single ring-shaped piezo element instead of the two piezo elements 35. Additionally, the MEMS element 12 can naturally also be used to detect a deflection of the mass element 110, due to a received acoustic signal 120, by the actuator element 32 and the piezo elements 35 applied thereto. The piezo elements 35 can again be applied as corresponding piezo layers to the actuator element 32 and can be controlled or read out by electronics (not shown). In particular, the piezo elements 35 can be controlled in a phase-shifted manner in order to achieve an S-shaped deflection of the actuator element 32.

Furthermore, the MEMS element 12 has a connecting element 52, which is in particular directly connected to the actuator element 32, for connecting the actuator element 32 to the mass element 110 of the acoustic transducer 102 and for transferring the movement of the actuator element 32 to the mass element 110, wherein the connecting element 52 has a higher stiffness than the actuator element 32. The connecting element 52 can be connected to the mass element 110 via a connecting means 111, which is, for example, designed as an adhesive. The higher stiffness of the connecting element 52 in comparison to the stiffness of the actuator element 32 can be achieved by a corresponding structuring of the actuator element 32 in that it is designed in the manner of a spoke in a plan view (not shown) and has corresponding recesses or apertures, whereas the connecting element 52 does not have such recesses or apertures.

The actuator element 32 is connected radially outwardly to a circumferential suspension element 72, which forms the rest of the substrate 22 and likewise has a higher stiffness than the actuator element 32, again achieved through the absence of corresponding recesses.

Furthermore, the geometry of the actuator element 32 is influenced by a cavity 42 in the substrate 22 and can in particular, inter alia, be defined thereby, wherein the cavity 42 is formed in the substrate 22 in such a way that the substrate 22 itself forms a depth stop 62 for the connecting element 52, and consequently indirectly for the actuator element 32, in the vertical direction in relation to the main extension plane 15. Here, the depth stop 62 is defined by a height h of the cavity 42. In particular, the cavity 42 has regions each of a different height h, wherein the region of the cavity 42 with the lowest height h in particular serves as a depth stop 62.

Accordingly, the cavity 42 has a lower height h in the region of the connecting element 52 than in the region of the actuator element 32 so that an indirect depth stop 62 for the actuator element 32 is formed via the connecting element 52.

The MEMS element 12 can again also be connected to a carrier element 130, which is, for example, designed as a PCB, via a connection 131, which is, for example, designed as an adhesive.

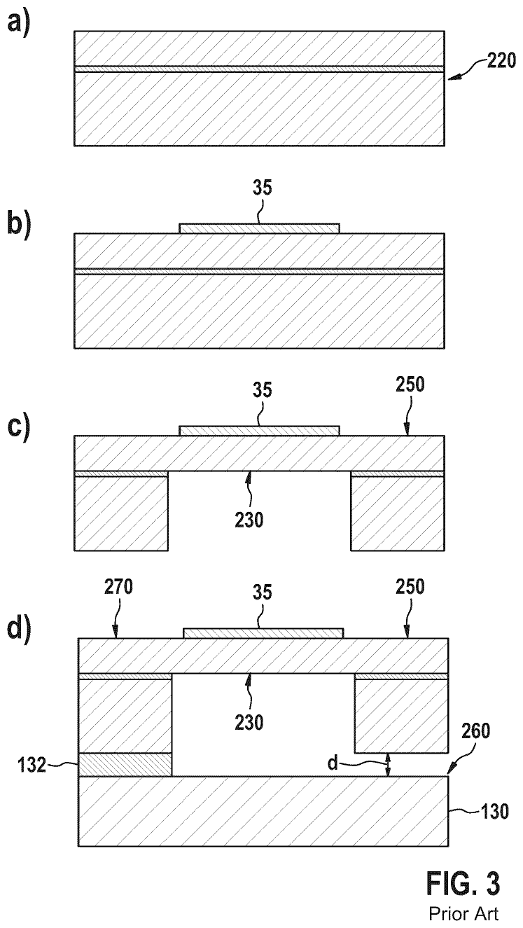

FIG. 3A-3D show method steps for producing a MEMS element according to the related art.

Thus, in a method step a) (FIG. 3A), a substrate 220 is provided, which is designed as an SOI wafer.

In a subsequent method step b) (FIG. 3B), a piezo element 35 can then be applied as a piezo layer.

In a method step c) (FIG. 3C), a trench process is then carried out in order to generate an actuator element 230 and a connecting element 250.

Subsequently, in a method step d) (FIG. 3D), a depth stop 260 is generated on one side and a suspension 270 for the actuator element 230 is generated on the other side in that the product from method step c) (FIG. 3C) is bonded by means of a wafer bond 132 to a carrier element 130 designed as a wafer, whereby a MEMS element is obtained, which is designed as a cantilever similarly to the MEMS element 11 according to FIG. 1. However, this results in the difficulty that very fragile structures on the wafer 130 have to be handled and separated during the production process in the related art. In addition, the vertical distance d for the depth stop 260 can only be adjusted with insufficient accuracy by means of the wafer bond 132. Furthermore, the geometry of the actuator element 230, and thus the resonance frequency, is defined according to method step c) (FIG. 3C) by a trench process, the dimensions of which may be inaccurate due to tilting and widening due to the process.

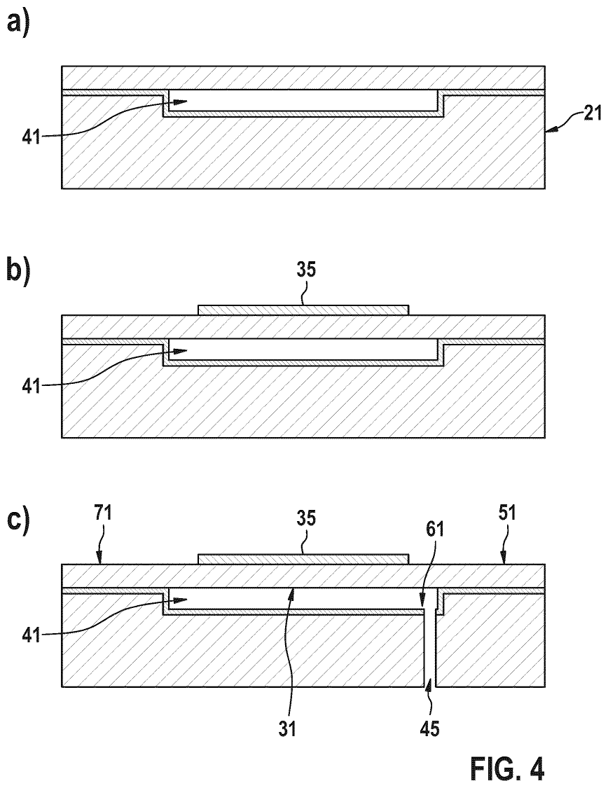

FIG. 4A-4C show method steps for producing a MEMS element similar to the first embodiment according to FIG. 1.

In a method step a) (FIG. 4A), a substrate 21 with a cavity 41 is provided, wherein the substrate is a cavity SOI wafer here. Alternatively, a substrate with a corresponding cavity may also be realized by means of a porous silicon process or by means of a trench process for the cavity.

In a method step b) (FIG. 4B), a piezo element 35 is then deposited as a piezoelectric layer and structured. This may include further layers not shown, such as electrode layers, barrier layers, etc.

In a method step c) (FIG. 4C), the cavity 41 is opened downward on one side, whereby an opening 45 is created, which separates the actuator element 31 and the connecting element 51 from the rest of the substrate 21 and makes them correspondingly movable. This results in a MEMS element which differs from the MEMS element 11 of FIG. 1 only in the number of piezo elements 35. The manufacturing sequence may include further steps, such as the creation of marks or the separation of the elements.

1-9. (canceled)

10. A MEMS element for moving a mass element of an acoustic transducer for generating and/or receiving acoustic signals, the MEMS element comprising:
a substrate;
an actuator element with at least one piezo element, applied to the actuator element configured to move the actuator element in a vertical direction in relation to a main extension plane of the MEMS element, wherein the geometry of the actuator element is influenced by a cavity in the substrate; and
a connecting element, arranged on the actuator element, configured to connect the actuator element to the mass element of the acoustic transducer and to transfer the movement of the actuator element to the mass element, wherein the connecting element has a greater stiffness than the actuator element, and wherein the cavity is formed in the substrate in such a way that the substrate itself forms a depth stop for the actuator element in the vertical direction.

11. The MEMS element according to claim 10, wherein the depth stop is defined by a height of the cavity.

12. The MEMS element according to claim 10, wherein the stiffness of the actuator element and/or of the connecting element is adjusted depending on a material and/or thickness and/or structuring of the actuator element and/or of the connecting element.

13. The MEMS element according to claim 10, wherein the connecting element is arranged laterally on the actuator element and forms a stump, wherein the cavity is open in such a way that the connecting element is separated from the rest of the substrate.

14. The MEMS element according to claim 10, wherein at least two piezo elements which can be controlled in a phase-shifted manner are applied to the actuator element.

15. The MEMS element according to claim 10, wherein the cavity has regions each of a different height, wherein a region of the cavity with a lowest height serves as a depth stop.

16. The MEMS element according to claim 10, wherein the actuator element and the connecting element are arranged concentrically in the main extension plane of the MEMS element, wherein the connecting element is arranged centrally, and wherein the cavity is parallel to the main extension plane and below the actuator element and the connecting element.

17. The MEMS element according to claim 16, wherein the cavity has a lower height in a region of the connecting element than in a region of the actuator element so that an indirect depth stop for the actuator element is formed via the connecting element.

18. An acoustic transducer, comprising:
a mass element; and
a MEMS element including:
a substrate,
an actuator element with at least one piezo element, applied to the actuator element configured to move the actuator element in a vertical direction in relation to a main extension plane of the MEMS element, wherein the geometry of the actuator element is influenced by a cavity in the substrate, and
a connecting element, arranged on the actuator element, configured to connect the actuator element to the mass element of the acoustic transducer and to transfer the movement of the actuator element to the mass element, wherein the connecting element has a greater stiffness than the actuator element, and wherein the cavity is formed in the substrate in such a way that the substrate itself forms a depth stop for the actuator element in the vertical direction.
